(19) United States
(12) Patent Application Publication
(10) Pub. No.: US 2019/0057859 A1
(43) Pub. Date: Feb. 21, 2019

(54) Methods and Systems for Forming a Mask Layer

(71) Applicant: IMEC VZW, Leuven (BE)

(72) Inventors: Boon Teik Chan, Leuven (BE); Jean-Francois de Marneffe, Bossut-Gottechain (BE)

(73) Assignee: IMEC VZW, Leuven (BE)

(21) Appl. No.: 16/103,370

(22) Filed: Aug. 14, 2018

(30) Foreign Application Priority Data
Aug. 18, 2017 (EP) 17186841.7

(51) Int. Cl. H01L 21/027; H01L 21/033

(52) U.S. Cl. CPC H01L 21/0273; H01L 21/0338; H01L 21/31144; H01L 21/0332; H01L 21/0337

(57) ABSTRACT

In one aspect, the present disclosure relates to a method. The method includes providing a substrate having a patterned layer thereon, the patterned layer including an opening that exposes the substrate. The method also includes selectively infiltrating the patterned layer with a metal or ceramic material, thereby reducing a dimension of the opening. The opening exposes the substrate after the dimension of the opening is reduced.

### CROSS-REFERENCE TO RELATED APPLICATIONS

The present application is a non-provisional patent application claiming priority to European Patent Application No. 17186841.7, filed on Aug. 18, 2017, the contents of which are hereby incorporated by reference.

### FIELD OF THE DISCLOSURE

The present disclosure relates to mask layers for use in the fabrication of devices such as semiconductor devices, and in particular to the reduction of a width of an opening in such a mask layer.

### BACKGROUND

Current optical lithography techniques are limited with regard to the minimum size of device features that can be achieved. This is problematic in several industries and particularly in the semiconductor industry where, for instance, demand for smaller nano-electronic transistors spurs demand for device features having sizes smaller than that which can be achieved via current optical lithography techniques. A way to reduce the dimensions (e.g. width) of an opening (e.g., trench or hole) in a mask layer obtained through a lithographic technique is to coat the insides of the opening using an atomic layer deposition (ALD) technique (see H.-S. Moon et al, Advanced functional materials, Vol. 24, Issue 27, p. 4343-4348). However, this method typically also coats the bottom of the opening, which is undesirable when the pattern of the mask is supposed to be transferred to the underlying layers. Indeed, when nanometer size features are desired and if an etching technique is used to open the coated bottom, then often also some of the side coating will be removed and the reduction of the dimensions of the opening may be partly or entirely undone. Opening the bottom selectively with respect to the sides, when both are coated with the same material, is a non-trivial challenge to resolve for nanometer size features because even directional etching techniques are not perfectly anisotropic. Furthermore, the ALD coating often has issues adhering to the underlying material, which can deteriorate the quality of the pattern that can be transferred. Moreover, ALD is typically performed on a hydrophilic surface, which limits the range of materials that the coating can be deposited on. Additionally, when the ALD coating is etched away during pattern transfer to the point of opening up to the material underneath, further etching may become difficult to control as the etch rate between the ALD coating and the underlying material typically differs considerably.

As such, there is a need for methods of making mask layers which alleviate some or all of the issues outlined above.

### SUMMARY

Embodiments of this disclosure can be helpful for providing improved mask layers and methods for making such mask layers (e.g., patterned mask layers).

Embodiments of this disclosure can be helpful for reducing a dimension (e.g., width and/or length) of a patterned opening, such as a trench or hole. Such a reduced dimension can be smaller than a dimension obtainable with conventional patterning and etching techniques. In some embodiments, the reduction in the dimension of an opening can be controlled.

Embodiments of this disclosure can be helpful for improving etch selectivity of the underlying substrate with respect to the mask layer.

Embodiments of this disclosure can be helpful for improving etch resistance of the mask layer.

Embodiments of this disclosure can be helpful for improving the lifetime of the mask layer during storage.

Embodiments of this disclosure can be helpful for reducing cost and increasing efficiency when compared to conventional methods.

In one aspect, the present disclosure relates to a method. The method includes providing a substrate having a patterned layer thereon, the patterned layer including an opening that exposes the substrate. The method also includes selectively infiltrating the patterned layer with a metal or ceramic material, thereby reducing a dimension of the opening. The opening exposes the substrate after the dimension of the opening is reduced.

The present disclosure may further relate to selectively etching, through the opening having the reduced dimension, the substrate with respect to the patterned layer.

In another aspect, the present disclosure relates to an assembly that includes a patterned layer on a substrate, the patterned layer including at least one opening exposing the substrate, the patterned layer being infiltrated with a concentration of a metal or ceramic material, the substrate being not infiltrated with the metal or ceramic material or being infiltrated with a lower concentration thereof.

In yet another aspect, the present disclosure relates to reducing the dimension of the opening of the patterned layer by at least 20%, at least 35%, or at least 50%.

Aspects of the disclosure are also set out in the accompanying independent and dependent claims. Features from the dependent claims may be combined with features of the independent claims and with features of other dependent claims as appropriate and not merely as explicitly set out in the claims.

The above and other characteristics, features and advantages of the present disclosure will become apparent from the following detailed description, taken in conjunction with the accompanying drawings, which illustrate, by way of example, the principles of the disclosure. This description is given for the sake of example only, without limiting the scope of the claims. The reference figures quoted below refer to the attached drawings.

### BRIEF DESCRIPTION OF THE FIGURES

Features of the disclosure will be better understood through the following illustrative and non-limiting detailed description of example embodiments, with reference to the appended drawings.

FIG. 1 is a graph showing atomic percentage as a function of the emission angle for different atomic orbitals, obtained using angle-resolved X-ray photoelectron spectroscopy (XPS) on a sample, in accordance with an example embodiment.

FIG. 2 is a graph showing elemental composition as a function of depth, obtained using elastic recoil detection (ERD) on a sample, in accordance with an example embodiment.

FIG. 3 shows elemental analysis mappings obtained using transmission electron microscopy energy dispersive x-ray spectroscopy for a sample, in accordance with an example embodiment.

FIG. 4 is a graph showing the thickness of a polyphthalaldehyde (PPA) film as a function of the number of cycles of a sequential infiltration synthesis (SIS) process performed at 80° C. (triangles) and 90° C. (squares), in accordance with an example embodiment.

FIG. 5a is a schematic representation of one step in the formation of a mask layer on a substrate and a subsequent pattern transfer into the substrate, in accordance with an example embodiment.

FIG. 5b is a schematic representation of one step in the formation of a mask layer on a substrate and a subsequent pattern transfer into the substrate, in accordance with an example embodiment.

FIG. 5c is a schematic representation of one step in the formation of a mask layer on a substrate and a subsequent pattern transfer into the substrate, in accordance with an example embodiment.

FIG. 5d is a schematic representation of one step in the formation of a mask layer on a substrate and a subsequent pattern transfer into the substrate, in accordance with an example embodiment.

FIG. 6a shows an atomic force microscopy depth profile along a direction x after one SIS cycle, for a sample according to an example embodiment.

FIG. 6b shows an atomic force microscopy depth profile along a direction x after two SIS cycles, for a sample according to an example embodiment.

FIG. 6c shows an atomic force microscopy depth profile along a direction x after four SIS cycles, for a sample according to an example embodiment.

FIG. 7 is a graph of the measured PPA etch rate for an N₂/H₂ plasma etch as a function of the number of SIS cycles, for samples according to an example embodiment.

FIG. 8a shows an atomic force microscopy depth profile along a direction x after one step in the formation of a mask layer on a substrate and subsequent pattern transfer, for samples according to an example embodiment.

FIG. 8b shows an atomic force microscopy depth profile along a direction x after one step in the formation of a mask layer on a substrate and subsequent pattern transfer, for samples according to an example embodiment.

FIG. 8c shows an atomic force microscopy depth profile along a direction x after one step in the formation of a mask layer on a substrate and subsequent pattern transfer, for samples according to an example embodiment.

FIG. 9a is a schematic representation of a top view of a patterned layer on a substrate (top) and mask layer on the substrate (bottom) for an opening, according to an example embodiment.

FIG. 9b is a schematic representation of a top view of a patterned layer on a substrate (top) and mask layer on the substrate (bottom) for an opening, according to an example embodiment.

FIG. 9c is a schematic representation of a top view of a patterned layer on a substrate (top) and mask layer on the substrate (bottom) for an opening, according to an example embodiment.

FIG. 9d is a schematic representation of a top view of a patterned layer on a substrate (top) and mask layer on the substrate (bottom) for an opening, according to an example embodiment.

FIG. 10 defines the length (l), width (w), and depth (d) of a right cylinder opening having irregular bases, according to an example embodiment.

FIG. 11 is a block diagram of a method, according to an example embodiment.

FIG. 12 is a block diagram of a method, according to an example embodiment.

In the different figures, the same reference signs refer to the same or analogous elements, unless context clearly dictates otherwise.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. The claims may, however, be embodied in many different forms and should not be construed as limited to the embodiments set forth herein; rather, these embodiments are provided by way of example.

The present disclosure will be described with respect to particular embodiments and with reference to certain drawings, but the scope of the claims is not limited thereto. The drawings described are schematic and non-limiting. In the drawings, the size of some of the elements may be exaggerated and not drawn to scale for illustrative purposes.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable with their antonyms under appropriate circumstances and that the embodiments of the disclosure described herein are capable of operation in other orientations than described or illustrated herein.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures, or characteristics may be combined in any suitable manner, as would be apparent to one of ordinary skill in the art from this disclosure, in one or more embodiments.

Similarly, it should be appreciated that in the description of embodiments of the disclosure, various features of the disclosure are sometimes grouped together in a single embodiment, figure, or description thereof for the purpose of streamlining the disclosure and aiding in the understanding of one or more various aspects. This method of disclosure, however, is not to be interpreted as reflecting an intention that each claim requires more features than are expressly recited in each claim. Rather, as the following claims reflect, various aspects are present in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the method. Thus, a processor with the necessary instructions for carrying out such a method or element of a method forms a means for carrying out the method or element of a method. Furthermore, an element described herein of an apparatus embodiment is an example of a means for carrying out the function performed by the element.

In the description provided herein, numerous specific details are set forth. However, it is understood that embodiments of the disclosure may be practiced without these specific details. In other instances, conventional methods, structures, and techniques have not been shown in detail in order not to obscure an understanding of this description.

Although the disclosure is not limited to a particular type of device, reference will be made to transistors. These devices generally include a first main electrode such as a drain, a second main electrode such as a source, and a control electrode such as a gate for controlling the flow of electrical charges between the first and second main electrodes.

The following terms are provided solely to aid in the understanding of the disclosure.

As used herein, when a metal or ceramic material is said to infiltrate a first material selectively with respect to a second material, this typically means that the first material is infiltrated more than the second material. In some examples, the metal or ceramic material could infiltrate the first material at least twice as much, at least five times as much, or at least ten times as much, as the second material. In some embodiments, the second material is not substantially infiltrated by the metal or ceramic material.

As used herein, when a first material is said to be etched selectively with respect to a second material, this typically means that the first material is etched faster than the second material. In some embodiments, the etching process would etch the first material at least twice as fast, at least five times as fast, or at least ten times as fast, as the second material. In some embodiments, the second material is not substantially etched by the etching process.

As used herein, an opening can have a depth, a width, and/or a length. If the opening has the shape of a cuboid having a face parallel to the surface of the substrate, the depth of the opening is generally the dimension of the cuboid measured perpendicularly to the surface of the substrate; the length of the opening is generally the extent of its longest edge parallel to the surface of the substrate; and the width of the opening is generally the extent of its shortest edge parallel to the surface of the substrate.

The present disclosure is applicable to openings of any shape. The opening may, for instance, be irregular along its length, width, and depth. The opening will often be a right cylinder, for instance, a right cylinder having polygonal bases of 3 or more sides, ellipsoidal bases, or irregular bases. To accommodate for this large variety of suitable opening shapes, the notions of length, width, and depth as used herein are defined as follow. As used herein, the depth, length, and width of an opening is generally respectively the depth, length, and width of its minimum bounding cuboid having a face parallel to the surface of the substrate.

The minimum bounding cuboid of an opening is generally the cuboid of smallest volume which comprises the entirety of the opening and which has a face parallel to the opening.

It was surprisingly found that infiltration of a patterned layer can lead to an expansion of the patterned layer, typically both perpendicular to and parallel to the substrate, and can, therefore, be used to reduce a dimension (e.g., the width and/or the length) of an opening within the patterned layer. This might allow for the formation of an opening with a dimension smaller than could be obtained without infiltration. Furthermore, infiltration with the metal or ceramic material typically allows the selectivity of the substrate etching with respect to the patterned layer to be increased. It also might allow the substrate resistance of the patterned layer to be increased. Additionally, infiltration can be regarded as a bulk modification of the patterned layer (as opposed to a mere surface modification). As such, the problems related to ALD coating as described in the background of the disclosure (e.g. adhesion and stress issues, uncontrolled etching after opening up of the ALD coating, etc.) are typically alleviated.

The mask layer is typically used in patterning the substrate underneath (cf. infra). The mask layer may, for example, function as a patterned hardmask layer during the pattern transfer.

The substrate typically includes a layer to be patterned. The layer to be patterned may, for example, be a semiconductor layer (e.g. a Si wafer, a Si nanowire, a MoS2 nanoribbon, or a graphene layer) or a dielectric layer (e.g. a layer of low-k material). The substrate may further include a hardmask layer (e.g. Si₃N₄ or SiO₂), above and typically on the layer to be patterned. The hardmask layer may, for example, be from 10 nm to 15 nm thick, e.g. 13 nm thick. A hardmask layer above the layer to be patterned can be useful in achieving a high quality of the transferred pattern. In embodiments, the hardmask may be a combination of an inorganic hardmask on an organic hardmask. For instance, the hardmask may be a SiO₂ inorganic hardmask layer provided on an APFTM film (Applied Materials, an amorphous carbon (a-C) deposited by CVD with precursors acetylene (C₂H₂) and propane (C₃H₆)) or a JSR HM8006TM film (an aromatic copolymer which contains naphthalene as a portion of the aromatic structure). The substrate can further include a soft material (e.g. having a Mohs hardness of 6 or below, 2 or below, or 1 or below), such as a softmask layer or a polymer layer, above the layer to be patterned and on the hardmask when a hardmask is present. A softmask layer can be useful in achieving a high quality of the transferred pattern. In some embodiments, the opening exposes a surface of the substrate and the surface comprises the soft material. Particularly when scanning probe lithography is used to pattern the opening in the patterned layer (cf. infra), the soft material can directly underlie the patterned layer. This might help the scanning probe tip to experience less wear.

In some embodiments, the opening can be a trench or a hole (e.g. a via). In some embodiments, a dimension (e.g., width) of the opening can measure 100 nm or less, 50 nm or less, or 20 nm or less, before infiltration is performed . The dimension may, for example, measure from 7 nm to 20 nm, from 10 nm to 15 nm, e.g. from 11 nm to 12 nm. In some embodiments, the dimension can measure from 7 nm, to 20 nm, from 10 nm to 15 nm, such as from 11 nm to 12 nm, before infiltration is performed, and can measure from 1 nm to 10 nm or from 2 nm to 5 nm after infiltration is performed. A dimension (e.g., width) of less than 10 nm or 5 nm after infiltration can be beneficial in a variety of applications and is typically difficult to achieve using current techniques.

In some embodiments, the patterned layer is a patterned resist layer and providing the substrate can include patterning the opening into the resist layer using lithography, such as thermal scanning probe lithography.

The lithography can be a scanning lithography. The scanning lithography could include a laser-scanning lithography, an electron beam lithography, or a thermal scanning probe lithography. These techniques are well suited for patterning amorphous organic materials comprising oxygen atoms in their structure and having a glass transition temperature above 100° C. (such as polyphthalaldehyde, PPA).

Scanning lithography can encompass an ensemble of lithographic techniques which use setups comparable to scanning probe microscopes and which typically advantageously allow sub diffraction limit resolutions (e.g. down to 10 nm and below). In scanning lithography, a scanning element (e.g. probe, laser, or electron beam) is used to pattern a layer, for example, based on mechanical, thermal, chemical, optical or electrical interactions (or combinations thereof). A setup for scanning lithography typically allows both scanning lithography and scanning microscopy to be performed; this advantageously allows the resist layer to be scanned and imaged prior to patterning, e.g. allowing the right target position to be determined, and/or after patterning, allowing the results of the patterning to be analyzed and to determine whether any corrections need to be made. In some embodiments, the scanning lithography can remove material from the resist layer to form the opening. An ablative scanning lithography can obviate the need for an additional development step. In other embodiments, the scanning lithography can change (e.g. oxidize) the nature of a section of the resist layer and patterning the opening may further comprise removing a section of the resist layer having a first nature selectively with respect to a section of the resist layer having a second nature.

In some embodiments, the scanning lithography is a thermal scanning probe lithography. Thermal scanning probe lithography is a technique which is typically ablative and well controllable while allowing features of 9 nm or smaller with a pitch of 9.5 nm or smaller to be patterned. It can be a maskless, all-dry, auto-correcting, table-top and/or direct overlay patterning technique and can have 3D patterning capability (see Pires et al., Science, 2010, vol. 328, issue 5979, pp 732-735). The thermal scanning probe can be a Si cantilever configured with a heatable tip. The thermal scanning probe can be useable for writing (i.e. patterning; scanning probe lithography) and imaging (i.e. scanning probe microscopy). In some embodiments, the tip can be heated up to 800° C. for patterning. In some embodiments, the tip can be cooled (e.g. for 6 μs) prior to imaging. In some embodiments, patterning the opening may comprise placing the tip into contact (e.g. electrostatically) with the resist layer for 1 μs to 5 μs.

Some embodiments include scanning a surface of the resist layer, thermally patterning a first section (e.g. a line) of the resist layer, cooling the tip, imaging the resist layer and analyzing the results; and optionally repeating the steps on a further section.

In some embodiments, the patterned layer is 5 nm to 20 nm thick, 9 nm to 11 nm thick, e.g. 10 nm thick. The patterned layer is typically a resist layer in which a metal or ceramic material can infiltrate. In other words, the patterned layer is typically not so dense to the point that the metal or ceramic material cannot infiltrate therein, e.g. the first and/or second precursor cannot infiltrate therein. Examples of such materials are organic materials comprising oxygen atoms in their structure. The patterned layer can include a material having a glass transition temperature above 100° C., or above 120° C. The patterned layer is generally amorphous. The patterned layer could include amorphous organic materials comprising oxygen atoms in their structure and having a glass transition temperature above 100° C. In some embodiments, the patterned layer is selected from molecular glasses having oxygen in their structures and polyphthalaldehyde (PPA). An example of suitable molecular glass is the following:

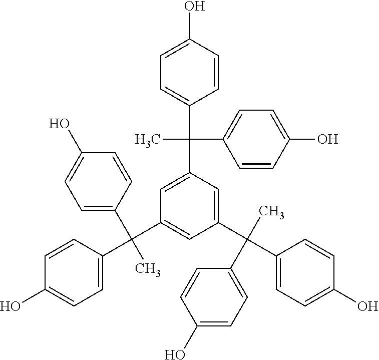 [SMILES: CC(c1ccc(O)cc1)(c1ccc(O)cc1)c1cc(C(C)(c2ccc(O)cc2)c2ccc(O)cc2)cc(C(C)(c2ccc(O)cc2)c2ccc(O)cc2)c1]

In some embodiments, the patterned layer includes a polyphthalaldehyde (PPA). In some embodiments, the resist layer includes a polyphthalaldehyde. The polyphthalaldehyde can include the following structure in its general formula.

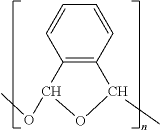

wherein n is from 3 to 50,000, or from 500 to 30,000. For instance, the polyphthalaldehyde can be a polymer or an oligomer. It may be linear or a cyclic. If it is a linear polymer, the linear polymer could include any form of end-groups. Some suitable linear polyphthalaldehyde are commercially available having a trichlorocarbamoyl end-group. Polyphthalaldehydes are materials which can be patterned using thermal scanning probe lithography and which can be infiltrated by a metal or ceramic material (e.g. they comprise ether groups to which a first precursor in a SIS process can bind; cf. infra).

In some embodiments, the ceramic material can include a metal oxide or a metalloid oxide such as an aluminum oxide, a titanium oxide, a silicon oxide, a ruthenium oxide or a hafnium oxide. These oxides can be infiltrated into the patterned layer, e.g. using a SIS process. In some embodiments, the ceramic material can include aluminum oxide (e.g. Al₂O₃).

In some embodiments, selectively infiltrating the patterned layer with a metal or ceramic material includes a sequential infiltration synthesis (SIS).

In some embodiments, the sequential infiltration synthesis includes exposing the patterned layer to a first metal or ceramic material precursor, and subsequently exposing the patterned layer to a second metal or ceramic material precursor.

As used herein the term “metal or ceramic material precursor” relates to a precursor in the formation of a metal or of a ceramic material. In the present disclosure, “metal or ceramic material precursor” can be precursors to metal oxides or to metalloid oxides.

Infiltrating the patterned layer with a metal or ceramic material can include exposing the patterned layer to a first metal or ceramic material precursor, thereby typically absorbing the first metal or ceramic material precursor in the patterned layer, and subsequently exposing the patterned layer to a second metal or ceramic material precursor, thereby typically chemically reacting both precursors to form the metal or ceramic material. The first and second metal or ceramic material precursors are typically reagents in the formation of the metal or ceramic material and are not typically metals or ceramic materials themselves. In some embodiments, the first and/or second metal or ceramic material precursors are in a gaseous phase. In yet more embodiments, both the first and second metal or ceramic material precursors are in a gaseous phase. The SIS process is typically performed in a reaction chamber. Typically, after exposing the patterned layer to the first metal or ceramic material precursor, a step of purging the reaction chamber with an inert gas (e.g. N₂) is performed. Typically, after exposing the patterned layer to the second metal or ceramic material precursor, a step of purging the reaction chamber with an inert gas (e.g. N₂) is performed. SIS can be performed at a temperature ranging from 10° C. to 110° C., from 20° C. to 90° C. A polyphtalaldehyde may, for example, decompose at a temperature of around 110° C. to 140 ° C. In order to improve the pattern fidelity, the SIS temperature can be lower, e.g. 25° C.

The first precursor of the metal or ceramic material typically comprises a metal . For instance, the first precursor can be an organometallic compound. The second precursor can be an oxidant. In some embodiments, the first precursor is trimethylaluminium and the second precursor is an oxidant (e.g. water). Other examples are RuO₄ for the first precursor and an oxidant (e.g. water) for the second precursor; TiCl₄ for the first precursor and an oxidant (e.g. water) for the second precursor; SiCl₄ for the first precursor and an oxidant (e.g. water) for the second precursor. In general, for the first precursor, any CVD/ALD precursors which can infiltrate the patterned layer selectively with respect to the substrate may be used. In some embodiments, the first precursor reacts with the second precursor at a temperature ranging from 10° C. to 110° C., e.g., from 20° C. to 90° C. Typically, the first precursor is able to infiltrate the patterned layer. The infiltrated ceramic material can be obtained through an oxidation of the first ceramic material precursor by means of the second ceramic material precursor (typically an oxidant).

The SIS process can be a suitable way for infiltrating the patterned layer in a controlled fashion; through a (repeatable) sequence of exposure to two (or more) metal or ceramic material precursors. Multiple parameters (e.g. exposure time, temperature, or partial pressure of the precursors) can be adapted within this process to achieve the desired level of infiltration. Use of trimethylaluminium within this process as a ceramic material precursor and subsequent oxidation by exposure to water, forming aluminum oxide infiltrated into the patterned layer, is disclosed herein.

The patterned layer is infiltrated to such an extent that at least one dimension (e.g., width or length) of the opening is reduced. Typically, also the depth will generally effectively increase due to the expansion of the patterned layer perpendicular to the substrate. If the opening is closed at at least a longitudinal extremity by the presence of the patterned layer, the method according to embodiments of the present disclosure can reduce the length of this opening. This situation is represented in FIGS. 9a, 9b, and 9d.

If the opening is closed at at least a lateral extremity by the presence of the patterned layer, the method according to embodiments of the present disclosure can reduce the width of this opening. This situation is represented in FIGS. 9a, 9b and 9c.

If the opening is closed at at least a lateral extremity and at at least a longitudinal extremity by the presence of the patterned layer, the method according to embodiments of the present disclosure can reduce both the width and the length of this opening. This situation is represented in FIGS. 9a and 9b.

If the opening is open at both its longitudinal extremities due to the absence of the patterned layer thereat, and is closed at both its lateral extremities by the presence of the patterned layer thereat, the method according to embodiments of the present disclosure can increase the length of this opening and can decrease the width of this opening. This situation is represented in FIG. 9c.

If the opening is open at both its lateral extremities due to the absence of the patterned layer thereat, and is closed at both its longitudinal extremities by the presence of the patterned layer thereat, the method according to embodiments of the present disclosure can increase the width of this opening and can decrease the length of this opening. This situation is represented in FIG. 9d. Although possible, this situation is not as advantageous as the situations represented by FIGS. 9 A, B, and C since an advantage of the present disclosure is its ability to facilitate achieving an opening with a width smaller than currently achievable by other techniques. Reducing the length is typically less important because it is typically longer than the width.

The extent of the dimensional reduction of the opening will typically depend on parameters of the infiltration process such as a number of repetition cycles, a duration of exposure to precursor(s), a concentration or partial pressure of a precursor, a reaction temperature, etc. In some embodiments, the dimension can be reduced by repeatedly and/or alternatingly exposing the patterned layer to the first precursor and the second precursor. In some embodiments, the patterned layer can be exposed to the first precursor and/or the second precursor 1 to 10 times. The absolute dimensional reduction is typically relatively linear with respect to the number of processing cycles and is thus typically controllable. The number of processing cycles can, of course, be increased beyond 10. Also, reducing the duration of each precursor exposure step typically leads to a larger number of processing cycles for an equivalent dimensional reduction. Similarly, an equivalent dimensional reduction can be obtained via fewer processing cycles by using a higher partial precursor pressure and/or longer precursor exposure times.

As disclosed herein, infiltration of the patterned layer with a metal or ceramic material can be performed selectively with respect to the substrate. This might yield increased etch selectivity and increased quality of the transferred pattern to the substrate. In some embodiments, the opening exposes a surface of the substrate, the surface belonging to a layer of a material not comprising oxygen atoms (i.e. free of oxygen atoms). In some embodiments, the surface includes a soft material (cf. supra). The surface can, for example, comprise an organic material, such as a polymer not comprising oxygen atoms, e.g. not comprising any hydroxyl, alkoxy, or carbonyl functional groups. The surface can, for example, be the surface of a layer of the organic material. The layer of organic material can, for example, be 5 nm to 7 nm thick. The polymer can, for example, be a polystyrene, such as a crosslinked polystyrene (x-PS). In some embodiments, the first precursor can diffuse into a soft material and bind therein to oxygen atoms, preventing the first precursor from being removed during a subsequent purging step and enabling the first precursor to react therein with the second precursor, resulting in a metal or ceramic material being infiltrated in the patterned layer. Trimethylaluminium is for example known to bind to carbonyl functional groups and more strongly to hydroxyl or alkoxy functional groups; furthermore, the oxygen in the aluminum oxide, formed from oxidizing the trimethylaluminium, typically acts as a further binding site in later SIS cycles. Conversely, if no oxygen atoms are present in the exposed substrate (e.g. in the soft material), the first precursor is typically flushed out during the purging phase and no first precursor is left in the material to react with the second precursor, thus no metal or ceramic material is infiltrated. As such, one can control which substrate will be infiltrated by means of the presence or absence of oxygen atoms therein.

In other embodiments, the surface comprises a hardmask material. Hardmask materials are typically denser than soft materials, thus not typically allowing the first precursor to diffuse therein and therefore preventing infiltration by the metal or ceramic material. The hardmask material might not comprise oxygen atoms. The hardmask material may, for example, be SiN, TiN or AlN. Even if the first precursor cannot diffuse into the hardmask material, the first precursor may still bind to oxygen atoms at the surface of a material such as SiOC, SiO₂ or SiON.

The present disclosure further relates to a method for patterning a substrate, comprising performing the method according to any aforementioned embodiment and further comprising selectively etching, through the opening having the reduced dimension, the substrate with respect to the infiltrated patterned layer.

Selectively etching the substrate with respect to the infiltrated patterned layer can comprise selectively etching the substrate at least with respect to the metal or ceramic material infiltrated within the patterned layer. In some embodiments, the etching comprises a plasma etching. A soft layer such as a polystyrene or cross-linked polystyrene layer may, for example, be selectively etched using an N₂/H₂, an N₂/O₂ or an Ar/O₂ plasma etching. A hardmask layer such as SiN may, for example, be selectively etched using a CH₃F/O₂/Ar plasma. In some embodiments, the method for patterning the substrate is used in the formation of quantum dots or single electron transistors, such as those used for quantum computing (e.g. solid-state room temperature quantum computing). In other embodiments, the method for patterning the substrate is used in the formation of a nanopore transistor, such as those used in nanopore transistor-based DNA sensing (where e.g. the patterning of a nanopore having a width smaller than 10 nm or smaller than 2 nm is desirable). In yet other embodiments, the method for patterning the substrate is used to pattern thin trenches, e.g. in a dielectric material.

In some embodiments, the method includes removing the infiltrated patterned layer, for example, using dry or wet etching solutions.

In another aspect, the present disclosure relates to an assembly comprising a patterned layer on a substrate, obtainable by any of the aforementioned methods.

For instance, in an embodiment, the present disclosure may relate to an assembly comprising a patterned layer on a substrate, the patterned layer comprising at least one opening exposing the substrate, the patterned layer being infiltrated with a concentration of a metal or ceramic material, the substrate being not infiltrated with the metal or ceramic material or being infiltrated with a lower concentration thereof.

In yet another aspect, the present disclosure relates to a use of sequential infiltration synthesis for reducing a dimension of an opening in a patterned layer.

In embodiments, the opening is formed using a scanning probe lithography, such as a thermal scanning probe lithography.

The disclosure includes a detailed description of several embodiments of the disclosure. It is clear that other embodiments of the disclosure can be configured according to the knowledge of the person skilled in the art without departing from the true technical teaching of the disclosure.

### EXAMPLE 1

### Sequential Infiltration Synthesis (SIS) into a Polyphtalaldehyde (PPA) Film

One or more SIS cycles were performed on a PPA film, each cycle comprising exposing the PPA film to trimethylaluminium (e.g., a first precursor) in a reaction chamber at a partial pressure of 0.1 Torr for 400 seconds/cycle, purging the reaction chamber with N₂ for 20 seconds (s) (inert gas), subsequently exposing the PPA film to water (second precursor) for 20 s and purging the reaction chamber again with N₂ for 2 min. The SIS process was performed at 25° C., unless otherwise specified. The nature of the infiltrated aluminum oxide (ceramic material) was investigated using various techniques.

### EXAMPLE 1a

### Distribution of the Infiltrated Aluminum Oxide

In a first sample, a PPA film with a thickness in the range of 10 nm to 26 nm is provided on a substrate and one cycle of SIS is performed on the PPA film as previously described in example 1. The infiltration of aluminum oxide into the PPA film was investigated by elemental analysis using angle resolved X-ray photoelectron spectroscopy (ARXPS) and elastic recoil detection (ERD).

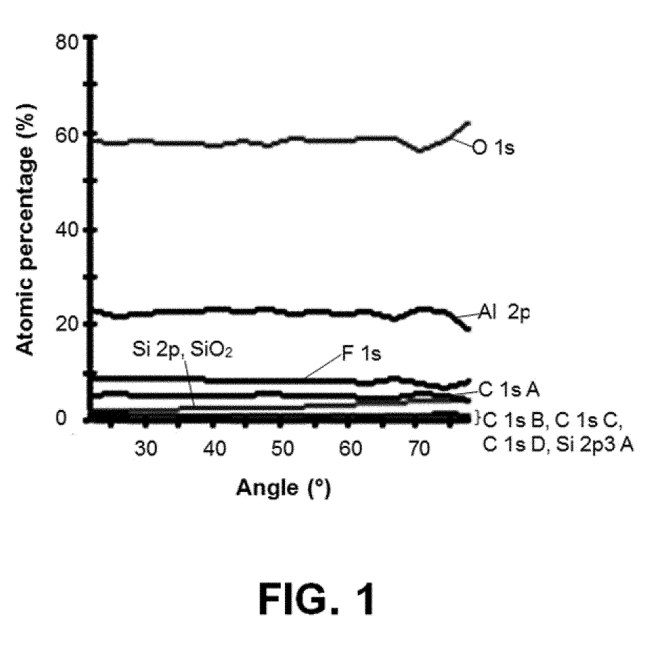

We now refer to FIG. 1, showing the atomic percentage as a function of the angle of incidence, obtained using XPS on the first sample, for different atomic orbitals. The relatively flat curves that were obtained indicated an even distribution of the infiltrated aluminum oxide over the investigated film thickness.

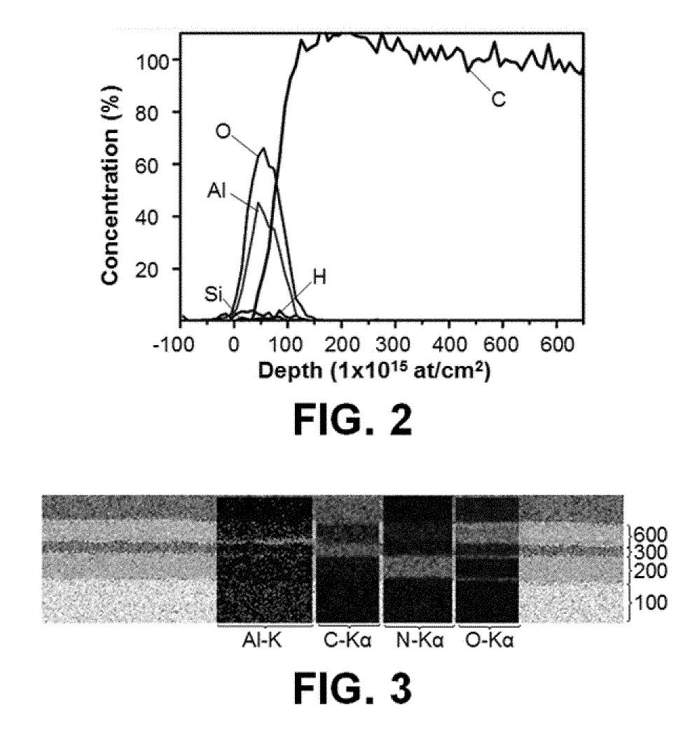

We now refer to FIG. 2, showing the elemental composition as a function of depth, obtained using ERD on the first sample. It was seen that Al and O, both attributed to the aluminum oxide, infiltrated about 10 nm into the PPA film. Furthermore, some Al and O were observed to be present in a layer of about 5 nm outside (e.g., on the surface of) the PPA film.

We now refer to FIG. 3. In a second sample, the substrate comprised a Si wafer (100) with a 13 nm thick SiN layer (200) and a 7 nm thick cross-linked polystyrene (x-PS) layer (300) thereon. A PPA layer of about 11 nm was provided on the x-PS layer (300) and a single SIS cycle was performed as previously described to form an infiltrated PPA layer (600). An elemental analysis of the second sample was performed using transmission electron microscopy (TEM) energy dispersive x-ray spectroscopy (EDS); this is shown in FIG. 3 consisting of the combined raw maps for all investigated energies (elements) overlaid in selected areas with the corresponding maps for the single elements Al, C, N, and O (based on their spectral lines Kα). In FIG. 3, any lighter spot indicates the presence of a detected energy (e.g. and a corresponding element) at that spot whereas a black spot indicates the absence thereof. From the Al map, it could be observed that aluminum oxide infiltrates into the PPA layer (600) selectively with respect to the x-PS layer (300). Furthermore, it was seen that the aluminum oxide mostly concentrates into an Al-rich layer at the top and the bottom of the PPA layer (600) at the first few cycles and distributes evenly across the bulk of the PPA as the number of cycles increases. Additionally, a small presence of Al could be seen near the x-PS (300)/SiN (200) interface. On the O map, two O rich layers near the x-PS (300)/SiN (200) and the SiN (200)/Si (100) interface could be observed; these were attributed to two native oxide layers. As such, it is tentatively suggested that the SIS precursors may be able to penetrate the PPA layer (600), without binding thereto, up to the SiN's (200) native oxide layer. In this view, the SIS precursors do not bind to the PPA layer (600) due to the lack of O therein but may bind to the O in the native oxide layer.

### EXAMPLE 1b

### PPA Film Thickness after Infiltration

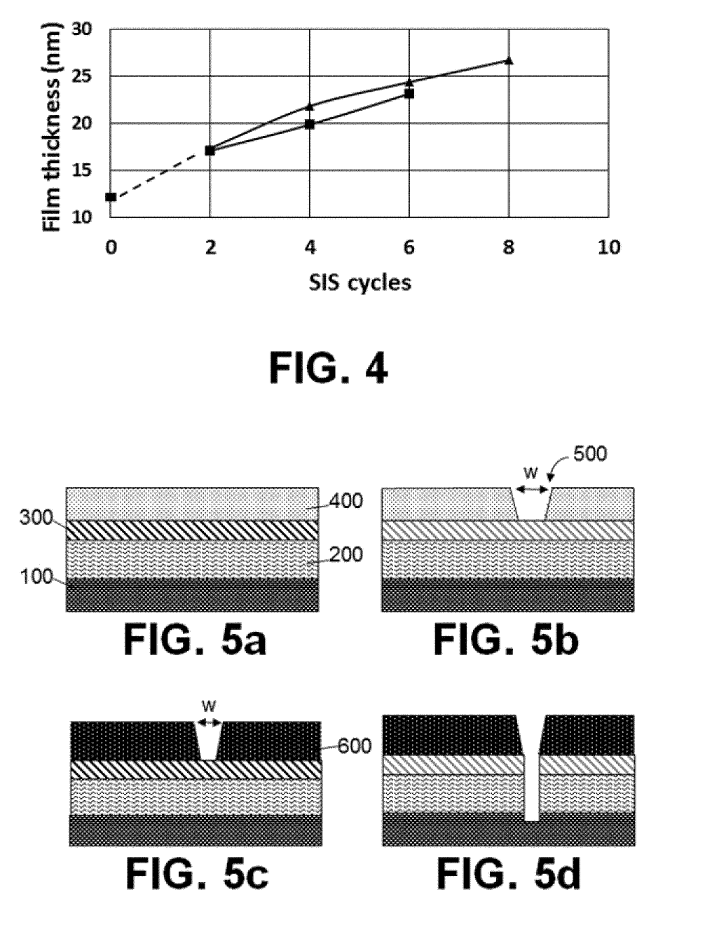

We now refer to FIG. 4, showing the thickness of a PPA film as a function of the number of cycles for a SIS process performed at 80° C. (triangles) and 90° C. (squares). For both temperatures, an almost linear increase of the film thickness could be observed for an increasing number of SIS cycles.

While FIG. 4 relates to the expansion of the PPA film in the direction perpendicular to the film (i.e. the thickness), it is believed (see example 2) that a similar expansion occurs in directions parallel to the film (e.g. the width or length). As such, when an opening is present in the PPA film, the film increasingly expands in the parallel directions with each SIS cycle and thereby reduces the width of any openings within the PPA film.

### EXAMPLE 2

### Sequential Infiltration Synthesis (SIS) into a Patterned Polyphtalaldehyde (PPA) Layer and Subsequent Pattern Transfer

### EXAMPLE 2a

### Patterning of a Polyphtalaldehyde (PPA) Layer

We now refer to FIG. 5a. A sample was provided, similar to the second sample of example 1b: the substrate comprised a Si wafer (100) with a 13 nm thick SiN layer (200) and a 7 nm thick cross-linked polystyrene (x-PS) layer (300) on the SiN layer (200), and a PPA layer (400) of about 11 nm was provided on the x-PS layer (300).

We now refer to FIG. 5b. At least one opening with a width (w) was formed in the PPA layer (400) using thermal scanning probe lithography (tSPL). Openings with a width as small as 9 nm or less and a pitch as low as 9.5 nm or less can be formed in PPA using tSPL.

### EXAMPLE 2b

### SIS into the Patterned PPA Layer

We now refer to FIG. 5c. One or more SIS cycles were performed on the PPA layer (400) to form an infiltrated PPA layer (600), thereby reducing the width (w) of the opening. Each cycle comprised exposing the PPA layer (400) to trimethylaluminium (first precursor) in a reaction chamber at a partial pressure of 0.1 Torr for 400 s/cycle, purging the reaction chamber with N₂ for 20 s (inert gas), subsequently exposing the PPA layer (400) to water (second precursor) for 20 s, and purging the reaction chamber again with N₂ for 2 min. The SIS process was done at 25° C. Starting from an opening with a small width (e.g., 12 nm or less) and using a sufficient number of SIS cycles, an opening with a width (w) of 5 nm or less can be obtained. It is noteworthy that the PPA layer, when not infiltrated, degrades thermally at room temperature within a few weeks while the infiltrated PPA layer does not show any signs of thermal degradation at room temperature over a corresponding period.

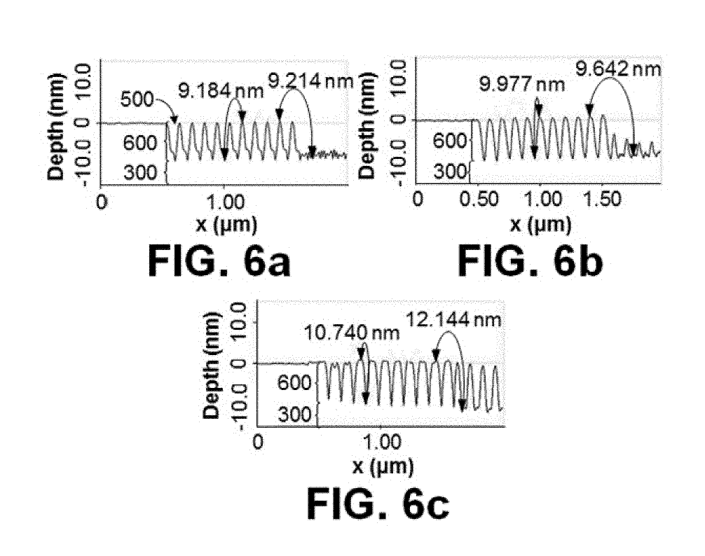

We now refer to FIGS. 6a-c, showing atomic force microscopy (AFM) depth profiles along a direction x for samples with a plurality of openings pitched at 100 nm and having undergone one (FIG. 6a), two (FIG. 6b) or four (FIG. 6c) SIS cycles. Also shown in FIGS. 6a-c are depth readouts as measured between the tips of each pair of the indicated arrows. The infiltration occurred selectively into the infiltrated PPA layer (600), with respect to the x-PS layer (300). It was observed that the infiltrated PPA layer (600) further expands for each additional SIS cycle. This expansion occurred both perpendicularly to the substrate, effectively deepening each opening, and parallel to the substrate, narrowing each opening.

### EXAMPLE 2c

### Pattern Transfer

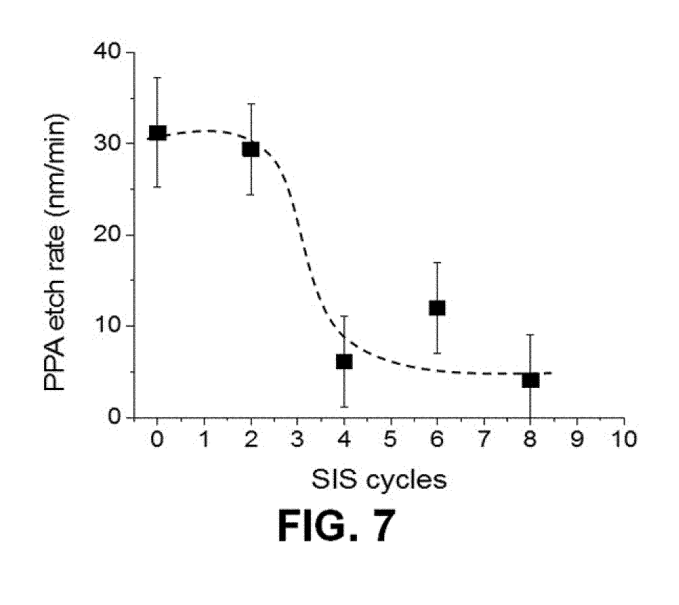

We now refer to FIG. 7, showing the measured PPA etch rate for an N₂/H₂ plasma etch as a function of the number of SIS cycles. It was seen that four or more SIS cycles increased the etch resistance of PPA by a factor of about four, as compared to a pure PPA film (i.e. zero SIS cycles).

We now refer to FIG. 5d. The pattern in the infiltrated PPA layer (600) is transferred to the substrate by plasma etching the x-PS layer (300) using an N₂/H₂ based chemistry. The pattern is further transferred by plasma etching the SiN layer (200) using a CH₃F/O₂/Ar based chemistry; it was observed that this type of etch may also recess the Si wafer.

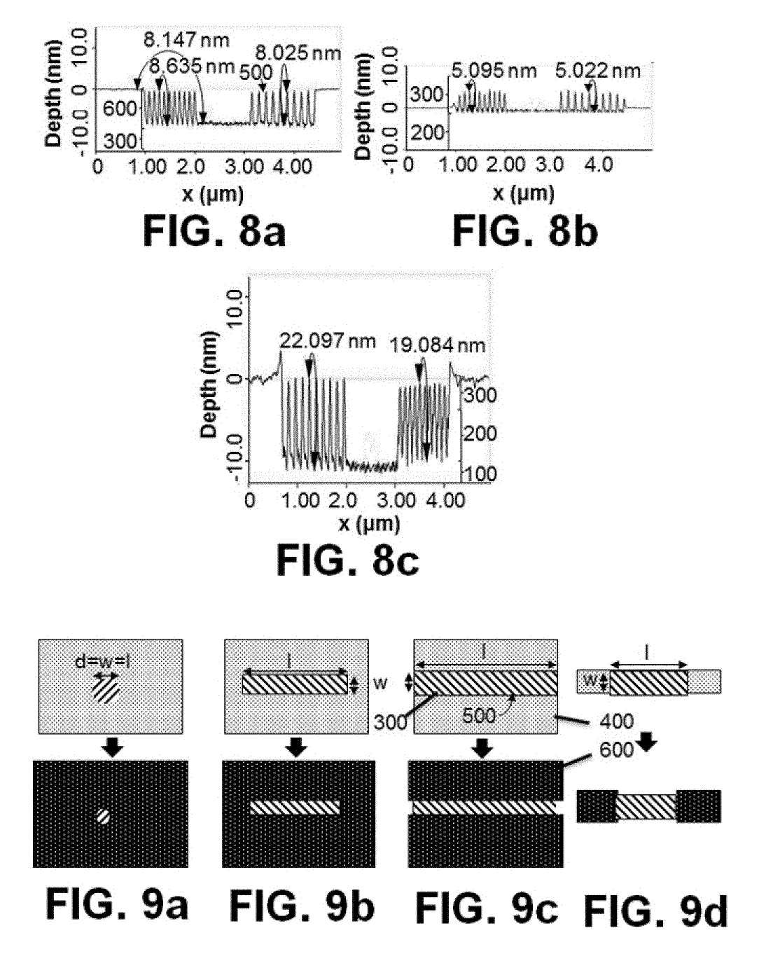

We now refer to FIGS. 8a-c, showing AFM depth profiles along a direction x after SIS (FIG. 8a), after etching the x-PS layer (300) (FIG. 8b) and after etching the SiN layer (200) (FIG. 8c). Also shown in FIGS. 8a-c are depth readouts as measured between the tips of each pair of the indicated arrows. The measured depth of 5 nm in FIG. 8b might indicate a not yet completed etch of the x-PS layer, but, nevertheless, the complete etch is seen in FIG. 8c. Since the layer thickness of the x-PS layer (300) and the SiN layer (200) is known (i.e. 7 nm and 13 nm respectively in this particular experimental structure), the full etching of these layers can be inferred from the measured depths of the openings in FIG. 8c (e.g. 22 nm). The slightly higher measured depth compared to the sum of the x-PS layer (300) and SiN layer (200) may either be due to the presence of some Al₂O₃ on top, adding to the depth, or due to a slight etching into the Si wafer (100). Nevertheless, it could thus be confirmed that the pattern in the PPA layer (200) can be successfully transferred into the x-PS layer (300) and into the SiN layer (200).

Additional measurements, which are not shown, were performed for etching beyond the SiN layer into the Si wafer. TEM analysis of the corresponding samples indicated a suitable pattern transfer into the SiN and 60 nm deep into the Si wafer.

FIGS. 9a-d show schematic representations of top views of patterned layers (400) on a substrate (300) (top) and mask layers (600) on the substrate (300) (bottom) for openings (500) differing in shape. FIG. 9a shows how a circular opening sees its diameter and therefore both its length and its width (which are equal) reduced during a method according to an embodiment of the present disclosure. FIG. 9b shows how a rectangular opening closed at both its lateral extremities and both its longitudinal extremities sees both its length and its width reduced during a method according to an embodiment of the present disclosure. FIG. 9c shows how a rectangular opening (a trench) closed at both its lateral extremities and open at both its longitudinal extremities sees its length augmented and its width reduced during a method according to an embodiment of the present disclosure. FIG. 9d shows how a rectangular opening open at both its lateral extremities and closed at both its longitudinal extremities sees its width augmented and its length reduced during a method according to an embodiment of the present disclosure.

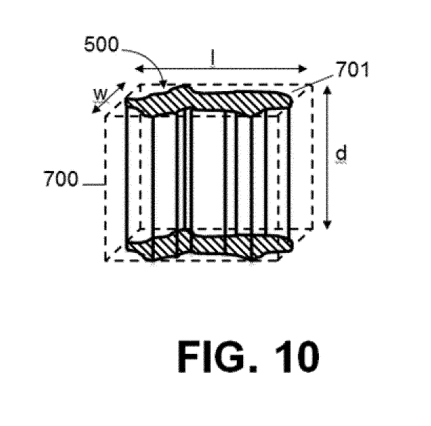

FIG. 10 defines the length (l), width (w) and depth (d) of a right cylinder opening (500) having irregular bases as being respectively the length (l), width (w) and depth (d) of its minimum bounding cuboid (700) having a face (701) parallel to the surface of the substrate.

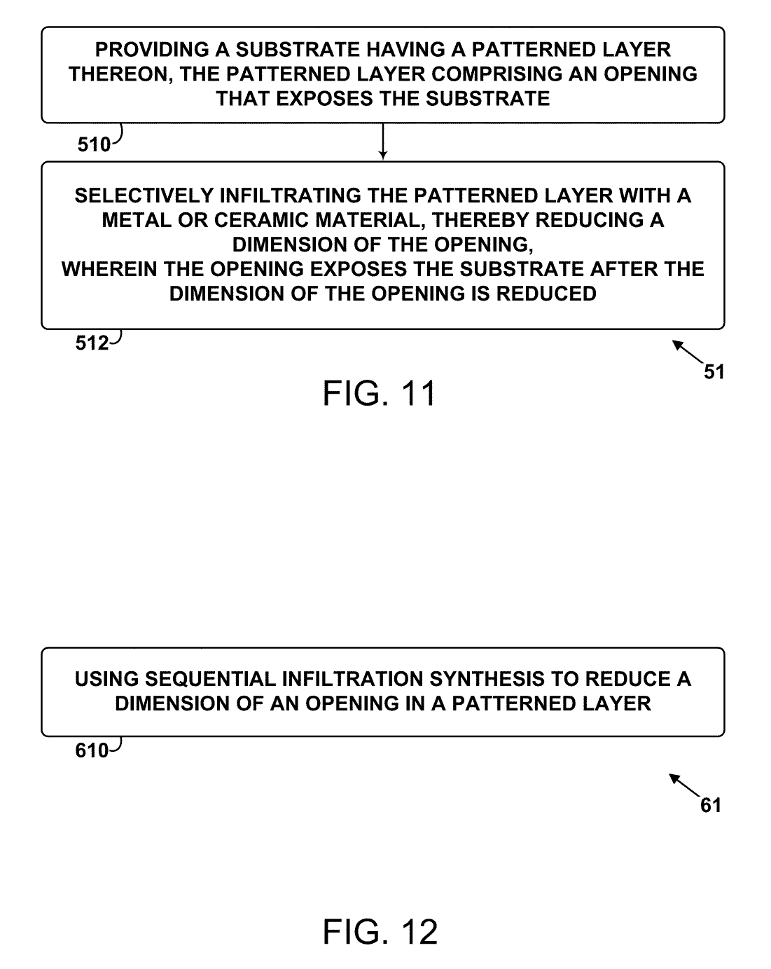

FIG. 11 is a block diagram of a method 51. At block 510, the method 51 includes providing a substrate having a patterned layer thereon, the patterned layer including an opening that exposes the substrate. At block 512, the method 51 includes selectively infiltrating the patterned layer with a metal or ceramic material, thereby reducing a dimension of the opening. In this context, the opening exposes the substrate after the dimension of the opening is reduced.

FIG. 12 is a block diagram of a method 61. At block 610, the method 61 includes using sequential infiltration synthesis to reduce a dimension of an opening in a patterned layer.

It is to be understood that although various embodiments, specific constructions and configurations, as well as materials, have been discussed herein for devices according to the present disclosure, various changes or modifications in form and detail may be made without departing from the scope and technical teachings of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used.

What is claimed is:

1. A method comprising:
providing a substrate having a patterned layer thereon, the patterned layer comprising an opening that exposes the substrate; and
selectively infiltrating the patterned layer with a metal or ceramic material, thereby reducing a dimension of the opening,
wherein the opening exposes the substrate after the dimension of the opening is reduced.

2. The method according to claim 1, wherein prior to reducing the dimension of the opening, the dimension measures 100 nm or less.

3. The method according to claim 1, wherein the dimension of the opening measures from 7 nm to 20 nm before the dimension is reduced and measures from 1 nm to 10 nm after the dimension is reduced.

4. The method according to claim 1, wherein the patterned layer is a patterned resist layer and wherein providing the substrate comprises:
patterning the opening into the patterned resist layer using lithography.

5. The method according to claim 4, wherein using lithography comprises using thermal scanning probe lithography.

6. The method according to claim 1, wherein the patterned layer comprises a polyphtalaldehyde.

7. The method according to claim 1, wherein the ceramic material comprises an aluminum oxide, a titanium oxide, a silicon oxide, a rubidium oxide, or a hafnium oxide.

8. The method according to claim 1, wherein selectively infiltrating the patterned layer comprises selectively infiltrating the patterned layer using a sequential infiltration synthesis.

9. The method according to claim 8, wherein using the sequential infiltration synthesis comprises:
exposing the patterned layer to a first precursor, and
exposing the patterned layer to a second precursor.

10. The method according to claim 9, wherein the first precursor comprises trimethylaluminium and wherein the second precursor comprises an oxidant.

11. The method according to claim 9, wherein selectively infiltrating the patterned layer comprises:
again exposing the patterned layer to the first precursor after exposing the patterned layer to the second precursor; and
again exposing the patterned layer to the second precursor after exposing the patterned layer to the first precursor.

12. The method according to claim 1, wherein the opening exposes a surface of the substrate and wherein the surface is made of an organic material free of oxygen atoms.

13. The method according to claim 1, further comprising:
selectively etching, through the opening having the reduced dimension, the substrate with respect to the patterned layer.

14. The method of claim 1, wherein reducing the dimension of the opening comprises reducing the dimension of the opening by at least 20%.

15. The method of claim 1, wherein prior to reducing the dimension of the opening, the dimension measures 50 nm or less, and measures from 2 to 5 nm after the dimension is reduced.

16. The method of claim 1, wherein prior to reducing the dimension of the opening, the dimension measures from 10 to 15 nm and measures from 2 to 5 nm after the dimension is reduced.

17. The method of claim 1, wherein reducing the dimension of the opening comprises reducing the dimension of the opening by at least 35% or at least 50%.

18. The method of claim 1, wherein prior to reducing the dimension of the opening, the dimension measures 20 nm or less, and measures from 2 to 5 nm after the dimension is reduced.

19. An assembly comprising a patterned layer on a substrate, the patterned layer comprising an amorphous organic material comprising oxygen and having a glass transition temperature above 100° C., the patterned layer comprising at least one opening exposing the substrate, the patterned layer being infiltrated with a concentration of a metal or ceramic material, the substrate being not infiltrated with the metal or ceramic material or being infiltrated with a lower concentration thereof.

20. A method comprising using sequential infiltration synthesis to reduce a dimension of an opening in a patterned layer.
